(19) United States
(12) Patent Application Publication
(10) Pub. No.: US 2024/0081073 A1
(43) Pub. Date: Mar. 7, 2024

(54) SEMICONDUCTOR DEVICE

(71) Applicant: Kioxia Corporation, Tokyo (JP)

(72) Inventors: Ryosuke UMINO, Kuwana Mie (JP); Daisuke IKENO, Yokkaichi Mie (JP); Masayuki KITAMURA, Yokkaichi Mie (JP); Akihiro KAJITA, Yokkaichi Mie (JP)

(73) Assignee: Kioxia Corporation, Tokyo (JP)

(21) Appl. No.: 18/459,795

(22) Filed: Sep. 1, 2023

(30) Foreign Application Priority Data
Sep. 2, 2022 (JP) 2022-140406

(51) Int. Cl. H10B 43/35; H10B 41/27; H10B 41/35; H10B 43/27

(52) U.S. Cl. CPC H10B 43/35; H10B 41/27; H10B 41/35; H10B 43/27

(57) ABSTRACT

A semiconductor device according to the present disclosure includes a first insulating film, a second insulating film, and a tungsten film provided between the first insulating film and the second insulating film, the tungsten film having a crystal particle, wherein a thickness T of the tungsten film in a first direction from the first insulating film toward the second insulating film and an average particle size APS of the crystal particle satisfy APS/T≤2 is satisfied.

### CROSS-REFERENCE TO RELATED APPLICATION

This application is based upon and claims the benefit of priority from Japanese Patent Application No. 2022-140406, filed on Sep. 2, 2022, the entire contents of which are incorporated herein by reference.

### FIELD

### Field of the Invention

A present embodiment relates to a semiconductor device.

### Background

A NAND flash memory having a three-dimensional structure manufactured by stacking a plurality of insulating layers and a plurality of metal layers has been proposed.

### BRIEF DESCRIPTION OF THE DRAWINGS

FIG. 1 is a block diagram showing a schematic configuration of a memory system of an embodiment.

FIG. 2 is a block diagram showing a schematic configuration of a semiconductor device of the embodiment.

FIG. 3 is a circuit diagram showing an equivalent circuit of the semiconductor device of the embodiment.

FIG. 4 is a perspective view showing a section perspective structure of the semiconductor device of the embodiment.

FIG. 5 is a cross-sectional view showing a sectional structure of a memory pillar of the embodiment.

FIG. 6 is a cross-sectional view showing a sectional structure taken along line VI-VI in FIG. 5.

FIG. 7 is a cross-sectional view showing part of a manufacturing step of the semiconductor device of the embodiment.

FIG. 8 is a cross-sectional view showing part of the manufacturing step of the semiconductor device of the embodiment.

FIG. 9 is a cross-sectional view showing part of the manufacturing step of the semiconductor device of the embodiment.

FIG. 10 is a cross-sectional view showing part of the manufacturing step of the semiconductor device of the embodiment.

FIG. 11 is a cross-sectional view showing part of the manufacturing step of the semiconductor device of the embodiment.

FIG. 12 is a cross-sectional view showing part of the manufacturing step of the semiconductor device of the embodiment.

FIG. 13 is a cross-sectional view showing part of the manufacturing step of the semiconductor device of the embodiment.

FIG. 14 is a cross-sectional view showing part of the manufacturing step of the semiconductor device of the embodiment.

FIG. 15 is a cross-sectional view showing part of the manufacturing step of the semiconductor device of the embodiment.

FIG. 16 is a cross-sectional view showing part of the manufacturing step of the semiconductor device of the embodiment.

FIG. 17A is a microscope image of a section of a semiconductor device 10 of the embodiment.

FIG. 17B is a microscope image of a section of a semiconductor device 200 of a comparative example.

FIG. 18 shows diffracted X-ray spectra of the semiconductor device 10 of the embodiment and the semiconductor device 200 of the comparative example.

FIG. 19 shows a graph of change in a specific resistance value of a word line in a thickness direction for each of the semiconductor device 10 of the embodiment and the semiconductor device 200 of the comparative example.

### DETAILED DESCRIPTION

A configuration of a semiconductor device 10 according to a present embodiment will be described below with reference to the accompanying drawings. The semiconductor device 10 according to the present embodiment is usable as a semiconductor storage device and is also referred to as a semiconductor storage device 10 in the following description. To facilitate understanding of the description, any identical constituent components in the drawings are denoted by the same reference sign when possible, and duplicate description thereof is omitted. In the following description, an X axis, a Y axis, and a Z axis are shown in some drawings. The X axis, the Y axis, and the Z axis constitute a right-handed three-dimensional orthogonal coordinate system. Hereinafter, a direction of an arrow along the X axis is referred to as an X-axis front side, and a direction opposite the arrow is referred to as an X-axis backside in some cases. This is the same for the other axes. The Z-axis front side and the Z-axis back side are also referred to as an “upper side” or a “top side”, or a “lower side” or a “down side”, respectively. The Z-axis direction is also referred to as a “stacking direction”. Planes orthogonal to the X axis, the Y axis, and the Z axis, respectively, are referred to as a YZ plane, a ZX plane, and an XY plane in some cases. However, these directions and the like are used for description of a relative positional relation, for convenience. Thus, these directions and the like define no absolute positional relation.

### 1. Embodiment

### 1.1 Configuration of Memory System

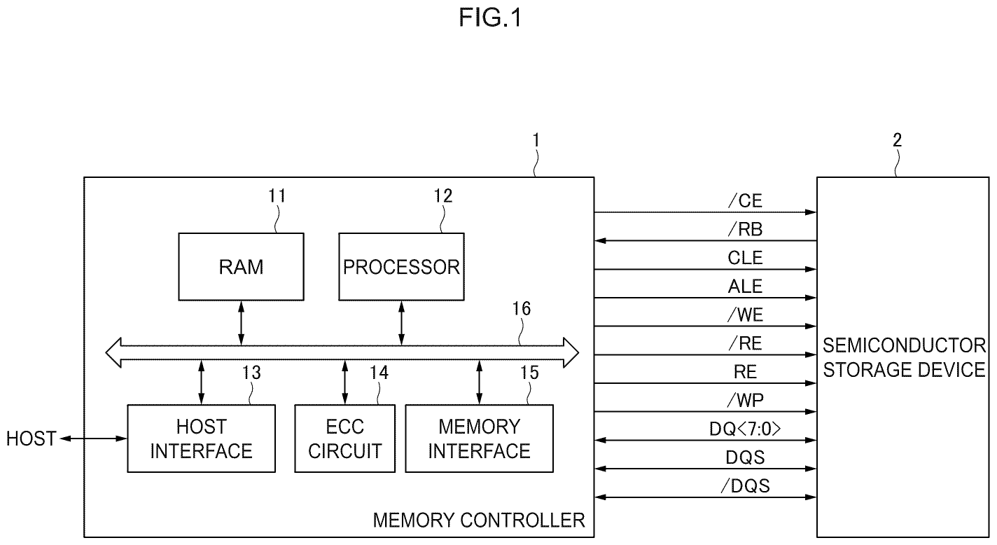

As shown in FIG. 1, a memory system according to the present embodiment includes a memory controller 1 and a semiconductor device 2. The semiconductor device 2 is a non-volatile storage configured as a NAND flash memory. The memory system is connectable to a host. The host is an electronic device such as a personal computer or a portable terminal. Note that although only one semiconductor device 2 is shown in FIG. 1, a plurality of semiconductor devices 2 may be provided in a memory system.

The memory controller 1 controls writing of data to the semiconductor device 2 in accordance with a writing request from the host. The memory controller 1 also controls reading of data from the semiconductor device 2 in accordance with a reading request from the host.

Signals such as a chip-enable signal/CE, a ready/busy signal/RB, a command-latch enable signal CLE, an address-latch enable signal ALE, a write enable signal/WE, read enable signals RE, /RE, a write protect signal/WP, a data signal DQ<7:0>, and data strobe signals DQS, /DQS are to be transmitted and received between the memory controller 1 and the semiconductor device 2.

The chip-enable signal/CE is a signal for enabling the semiconductor device 2. The ready/busy signal/RB is a signal for indicating whether the semiconductor device 2 is in a ready state or in a busy state. The “ready state” refers to a state in which an external command is to be received. The “busy state” is a state in which no external command is to be received. The command-latch enable signal CLE is a signal indicating that the signal DQ<7:0> is a command. The address-latch enable signal ALE is a signal indicating that the signal DQ<7:0> is an address. The write enable signal/WE, which is a signal for taking a received signal into the semiconductor device 2, is to be asserted every time when the memory controller 1 receives a command, an address and data. The memory controller 1 instructs the semiconductor device 2 to take the signal DQ<7:0> while the signal/WE is an “L (Low)” level.

The read enable signals RE, /RE are signals from the memory controller 1 to read data from the semiconductor device 2. The read enable signals RE, /RE are used for, for example, controlling an operation timing of the semiconductor device 2 for outputting the signal DQ <7:0>. The write protect signal/WP is a signal for providing instructions of inhibition of writing and erasure of data to the semiconductor device 2. The signal DQ<7:0> is an entity of data transmitted and received between the semiconductor device 2 and the memory controller 1, which includes a command, an address and data. The data strobe signals DQS, /DQS are signals for controlling a timing for input and output of the signal DQ<7:0>.

The memory controller 1 includes a RAM 11, a processor 12, a host interface 13, an ECC circuit 14, and a memory interface 15. The RAM 11, the processor 12, the host interface 13, the ECC circuit 14, and the memory interface 15 are connected to each other through an internal bus 16.

The host interface 13 outputs a request, user data (write data), etc., received from the host to the internal bus 16. The host interface 13 also transmits user data read from the semiconductor device 2, a response from the processor 12, etc., to the host.

The memory interface 15 controls, on the basis of instructions from the processor 12, a process of writing user data or the like to the semiconductor device 2 and a process of reading user data or the like from the semiconductor device 2.

The processor 12 collectively controls the memory controller 1. The processor 12 is, for example, a CPU or an MPU. The processor 12 performs, in response to receiving a request from the host through the host interface 13, a control in accordance with the request. For example, the processor 12 instructs the memory interface 15 to write user data and parity to the semiconductor device 2 in accordance with the request from the host. The processor 12 also instructs the memory interface 15 to read user data and parity from the semiconductor device 2 in accordance with the request from the host.

The processor 12 determines a storage region (a memory region) on the semiconductor device 2 for user data accumulated in the RAM 11. The user data is held in the RAM 11 through the internal bus 16. The processor 12 determines the memory region for data (page data) per writing unit, i.e., per page. User data held in one page in the semiconductor device 2 is hereinafter also referred to as “unit data”. The unit data is usually encoded by adding a correction code and held in the semiconductor device 2 as a code word (Codeword). In the present embodiment, encoding is not essential. Although the memory controller 1 may hold the unit data in the semiconductor device 2 without encoding the unit data, a configuration in which encoding is performed is shown as an example in FIG. 1. In a case in which the memory controller 1 does not perform encoding, page data matches with unit data. One code word may be generated on the basis of one piece of unit data, or one code word may be generated on the basis of divided data provided by dividing unit data. Alternatively, one code word may be generated by using a plurality of pieces of unit data.

The processor 12 determines a writing destination, i.e., a memory region on the semiconductor device 2, for each unit data. Each memory region on the semiconductor device 2 is assigned with a physical address. With use of the physical address, the processor 12 manages the memory region, which is a destination for the unit data to be written. The processor 12 instructs the memory interface 15 to write the user data to the semiconductor device 2 with the determined memory region (physical address) designated. The processor 12 manages correspondence between a logical address (a logical address managed by the host) and the physical address of the user data. In a case of receiving a reading request including a logical address from the host, the processor 12 identifies the physical address corresponding to the logical address and instructs the memory interface 15 to read the user data with the physical address designated.

The ECC circuit 14 encodes user data held in the RAM 11, thereby generating a code word. The ECC circuit 14 decodes a code word read from the semiconductor device 2.

The RAM 11 temporarily holds user data received from the host until the user data is stored in the semiconductor device 2 or temporarily holds data read from the semiconductor device 2 until the data is transmitted to the host. The RAM 11 is, for example, a general-purpose memory such as an SRAM or a DRAM.

FIG. 1 shows a configuration example where the memory controller 1 includes both the ECC circuit 14 and the memory interface 15. However, the ECC circuit 14 may be incorporated in the memory interface 15. Alternatively, the ECC circuit 14 may be incorporated in the semiconductor device 2. Specific configurations and locations of the components shown in FIG. 1 are not limitative.

In a case of receiving a writing request from the host, the memory system in FIG. 1 operates as follows. The processor 12 causes the RAM 11 to temporarily store data to write. The processor 12 reads the data stored in the RAM 11 and inputs the data to the ECC circuit 14. The ECC circuit 14 encodes the input data and inputs a code word to the memory interface 15. The memory interface 15 writes the input code word to the semiconductor device 2.

In a case of receiving a reading request from the host, the memory system in FIG. 1 operates as follows. The memory interface 15 inputs a code word read from the semiconductor device 2 to the ECC circuit 14. The ECC circuit 14 decodes the input code word and causes the RAM 11 to store the decoded data. The processor 12 transmits the data stored in the RAM 11 to the host through the host interface 13.

### 1.2 Configuration of Semiconductor Device

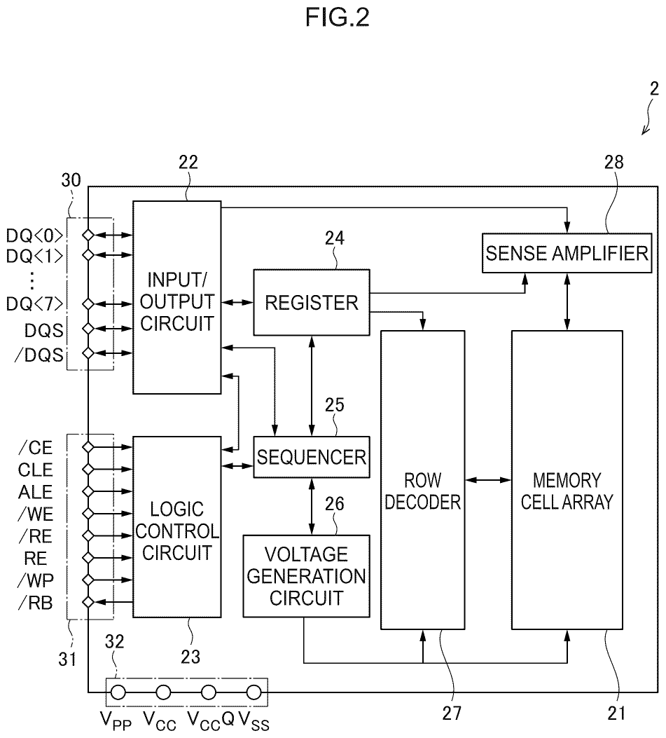

As shown in FIG. 2, the semiconductor device 2 includes a memory cell array 21, an input/output circuit 22, a logic control circuit 23, a register 24, a sequencer 25, a voltage generation circuit 26, a row decoder 27, a sense amplifier 28, a pad group for input/output 30, a pad group for logic control 31, and a terminal group for power input 32.

The memory cell array 21 is a section that stores data. The memory cell array 21 includes a plurality of memory cell transistors associated with a plurality of bit lines and a plurality of word lines.

The signal DQ<7:0> and the data strobe signals DQS, /DQS are transmitted and received between the input/output circuit 22 and the memory controller 1. The input/output circuit 22 also forwards a command and an address in the signal DQ<7:0> to the register 24. In addition, write data and read data are transmitted and received between the input/output circuit 22 and the sense amplifier 28.

The logic control circuit 23 receives a control signal such as the chip-enable signal/CE, the command-latch enable signal CLE, the address-latch enable signal ALE, the write enable signal/WE, the read enable signals RE, /RE, and the write protect signal/WP from the memory controller 1. The logic control circuit 23 also forwards the ready/busy signal/RB to the memory controller 1, externally informing the state of the semiconductor device 2.

The register 24 temporarily holds various kinds of data. For example, the register 24 holds commands providing instructions for a writing operation, a reading operation, an erasure operation, and the like. The commands are input to the input/output circuit 22 from the memory controller 1 and then forwarded from the input/output circuit 22 to the register 24 to be held. The register 24 also holds an address corresponding to the above-described command. The address is input to the input/output circuit 22 from the memory controller 1 and then forwarded from the input/output circuit 22 to the register 24 to be held. The register 24 also holds status information indicating an operation state of the semiconductor device 2. The status information is updated by the sequencer 25 in accordance with an operation state of the memory cell array 21 or the like. The status information is output as a state signal from the input/output circuit 22 to the memory controller 1 at the request of the memory controller 1.

The sequencer 25 controls the operations of sections including the memory cell array 21 on the basis of a control signal input from the memory controller 1 to the input/output circuit 22 and the logic control circuit 23.

The voltage generation circuit 26 is a section that generates a voltage required for each of a writing operation, a reading operation and an erasure operation of data in the memory cell array 21. Examples of such a voltage include a voltage applied to each of the plurality of word lines and the plurality of bit lines in the memory cell array 21. The operation of the voltage generation circuit 26 is controlled by the sequencer 25.

The row decoder 27 is a circuit configured as a switch group for applying a voltage to each of the plurality of word lines in the memory cell array 21. The row decoder 27 receives a block address and a row address from the register 24, selects a block on the basis of the block address, and selects a word line on the basis of the row address. The row decoder 27 switches opening and closing of the switch group such that a voltage from the voltage generation circuit 26 is applied to the selected word line. The operation of the row decoder 27 is controlled by the sequencer 25.

The sense amplifier 28 is a circuit for adjusting a voltage applied to the bit lines in the memory cell array 21 and for reading the voltage of the bit lines and converting it to data. In reading data, the sense amplifier 28 acquires data read from the memory cell transistors in the memory cell array 21 to the bit lines and forwards the acquired read data to the input/output circuit 22. In data writing, the sense amplifier 28 forwards data, which is to be written through the bit lines, to the memory cell transistors. The operation of the sense amplifier 28 is controlled by the sequencer 25.

The pad group for input/output 30 is a section provided with a plurality of terminals (pads) for transmission and reception of the signals between the memory controller 1 and the input/output circuit 22. The terminals are provided individually corresponding one-to-one to the signal DQ<7:0> and the data strobe signals DQS, /DQS.

The pad group for logic control 31 is a section provided with a plurality of terminals for transmission and reception of the signals between the memory controller 1 and the logic control circuit 23. The terminals are individually provided corresponding one-to-one to the chip-enable signal/CE, the command-latch enable signal CLE, the address-latch enable signal ALE, the write enable signal/WE, the read enable signals RE, /RE, the write protect signal/WP, and the ready/busy signal/RB.

The terminal group for power input 32 is a section provided with a plurality of terminals for receiving application of voltages required for the operations of the semiconductor device 2. The voltages to be applied to the respective terminals include power source voltages Vcc, VccQ, and Vpp, and a grounding voltage Vss. The power source voltage Vcc, which is a circuit power source voltage externally given as an operation power source, is, for example, a voltage of 3.3 V approximately. The power source voltage VccQ is, for example, a voltage of 1.2 V. The power source voltage VccQ is a voltage that is to be used for transmission and reception of a signal between the memory controller 1 and the semiconductor device 2. The power source voltage Vpp, which is a power source voltage higher than the power source voltage Vcc, is, for example, a voltage of 12 V.

### 1.3 Electronic Circuit Configuration of Memory Cell Array

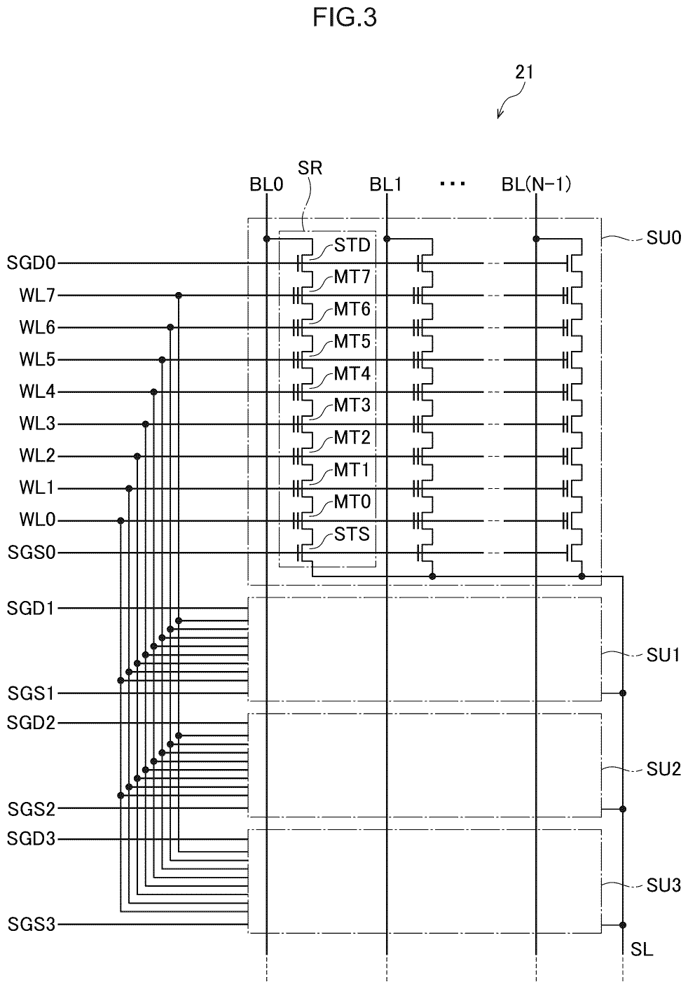

Subsequently, an electronic circuit configuration of the memory cell array 21 will be described. As shown in FIG. 3, the memory cell array 21 includes a plurality of string units SU0 to SU3. The string units SU0 to SU3 each include a plurality of NAND strings SR. The NAND strings SR each include, for example, eight memory cell transistors MT0 to MT7 and two select transistors STD and STS. Note that the respective numbers of the memory cell transistors and the select transistors included in each of the NAND strings SR are optionally changeable.

The plurality of string units SU0 to SU3 are in the form of one block as a whole. Note that, in FIG. 3, only a single block is shown but the memory cell array 21 may include a plurality of such blocks in reality.

Hereinafter, the string units SU0 to SU3 are sometimes also referred to as “string units SU” without distinction. The memory cell transistors MT0 to MT7 are also referred to as “memory cell transistors MT” without distinction.

The memory cell array 21 includes N bit lines BL0 to BL(N-1). Note that “N” is a positive integer. The string units SU each include the same number of NAND strings SR as the number of N of the bit lines BL0 to BL(N-1). The memory cell transistors MT0 to MT7 provided to the NAND strings SR are arranged in series between a source of the select transistor STD and a drain of the select transistor STS. A drain of the select transistor STD is connected to one of the plurality of bit lines BL0 to BL(N-1). A source of the select transistor STS is connected to a source line SL. In the description below, the bit lines BL0 to BL(N-1) are sometimes also referred to as “bit lines BL” without distinction.

The memory cell transistors MT each are configured as a transistor having a charge storage layer at a gate portion. The amount of charges accumulated in the charge storage layer corresponds to data held in the memory cell transistors MT. The memory cell transistors MT may each be a charge-trap transistor including, for example, a silicon nitride film as the charge storage layer or a floating gate transistor including, for example, a silicon film as the charge storage layer.

Gates of the plurality of select transistors STD included in the string unit SU0 are all connected to the select gate line SGD0. A voltage for switching opening and closing of the select transistors STD is applied to the select gate line SGD0. Similarly, the string units SU1 to SU3 are connected to select gate lines SGD1 to SGD3, respectively.

Gates of the plurality of select transistors STS included in the string unit SU0 are all connected to a select gate line SGS0. A voltage for switching opening and closing of the select transistors STS is applied to the select gate line SGS0. Similarly, the string units SU1 to SU3 are connected to select gate lines SGS1 to SGS3, respectively. Note that the string units SU0 to SU3, which are in the form of one block, may share a select gate line and the gates of the select transistors STS of the string units SU0 to SU3 may be connected to the select gate line in common.

Gates of the memory cell transistors MT0 to MT7 are connected to word lines WL0 to WL7. A voltage is applied to the word lines WL0 to WL7 for the purpose of switching opening and closing of the memory cell transistors MT0 to MT7, changing the amount of charges accumulated in the respective charge storage layers of the memory cell transistors MT0 to MT7, or the like.

Writing and reading of data in the semiconductor device 2 are collectively performed for each unit referred to as a “page” on the plurality of memory cell transistors MT connected to one of word lines WL in one of the string units SU. In contrast, erasure of data in the semiconductor device 2 is collectively performed on all the memory cell transistors MT included in the block. A variety of known methods are usable as specific methods for performing such writing, reading, and erasure of data, and accordingly, detailed description of the methods is omitted.

### 1.4 Structure of Semiconductor Device

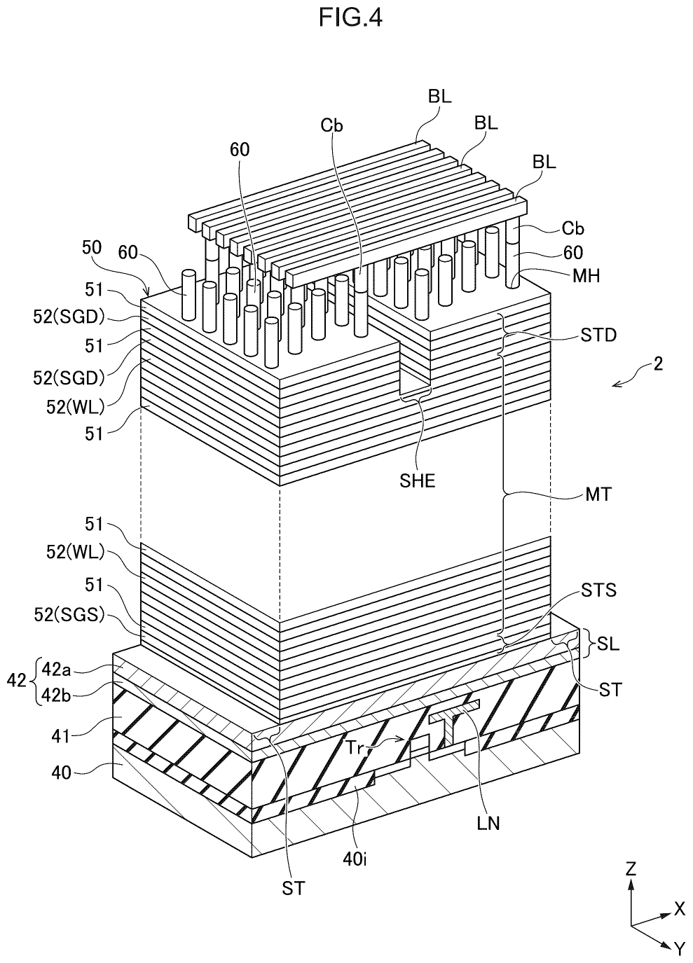

Subsequently, the structure of the semiconductor device 2, particularly, the structure of the vicinity of the memory cell array 21 will be specifically described. As shown in FIG. 4, the semiconductor device 2 includes a substrate 40, an insulator layer 41, a semiconductive layer 42, and a stacked body 50.

The substrate 40 is a plate-shaped member having a flat surface on the Z-axis direction side. The substrate 40 is, for example, a silicon wafer. The insulator layer 41 and the semiconductive layer 42 are formed on the upper surface of the substrate 40 as a multi-layer film by, for example, chemical vapor deposition (CVD) film formation. For example, an element separation region 40i is provided on a surface of the substrate (semiconductor substrate) 40. The element separation region 40i is an insulation region containing, for example, silicon oxide, and part thereof partitions the source and drain regions of a transistor Tr.

The insulator layer 41 is formed of an insulating material such as silicon oxide. In the insulator layer 41, peripheral circuits including a transistor Tr, a wire LN, and the like are formed at a bottom part contacting the substrate 40. The peripheral circuits serve as the sense amplifier 28 and the row decoder 27 shown in FIG. 2. The peripheral circuits are entirely covered by the insulator layer 41.

The semiconductive layer 42 is a layer that functions as the source line SL in FIG. 3. The semiconductive layer 42 is formed of, for example, a silicon-containing material such as a polycrystalline silicon doped with impurities. The semiconductive layer 42 is embedded in the insulator layer 41 below the memory cell array 21.

Note that the semiconductive layer 42 may be entirely formed of a semiconductor material such as silicon but may be formed in a stacked structure of at least two layers including a semiconductive layer 42a and a conductive layer 42b as shown in FIG. 4. The semiconductive layer 42a is formed of a semiconductor material such as silicon (polysilicon). The conductive layer 42b is formed of a metallic material such as tungsten.

The stacked body 50 is provided on the upper surface of the semiconductive layer 42. The stacked body 50 has a structure in which a plurality of insulator layer 51 and a plurality of conductive layer 52 are alternately stacked in the Z-axis direction. The insulator layers 51 and the conductive layers 52 are formed on the upper surface of the semiconductive layer 42 as a multi-layer film by, for example, a film formation method using the CVD method.

The conductive layers 52 are formed of a material containing, for example, tungsten and has conductivity. The conductive layers 52 are used as, for example, the word lines WL0 to WL7 and the select gate lines SGS1 and SGD1 in FIG. 3. Each insulator layer 51 is disposed between the conductive layers 52 adjacent to each other and electrically insulates the conductive layers 52 from each other. Each insulator layer 51 corresponds to an “insulating film” in the present embodiment, and each conductive layer 52 corresponds to a “tungsten film” in the present embodiment. Methods of manufacturing the insulator layers 51 and the conductive layers 52 in the present embodiment will be described in detail later.

A plurality of memory holes MH are formed to extend (penetrate) through the stacked body 50 in the Z-axis direction. A memory pillar 60 is formed inside each memory hole MH. The memory pillars 60 are each formed in a region from one positioned uppermost among the insulator layers 51 to the semiconductive layer 42 in the Z-axis direction. The memory pillars 60 correspond one-to-one to a NAND string SR shown in FIG. 3.

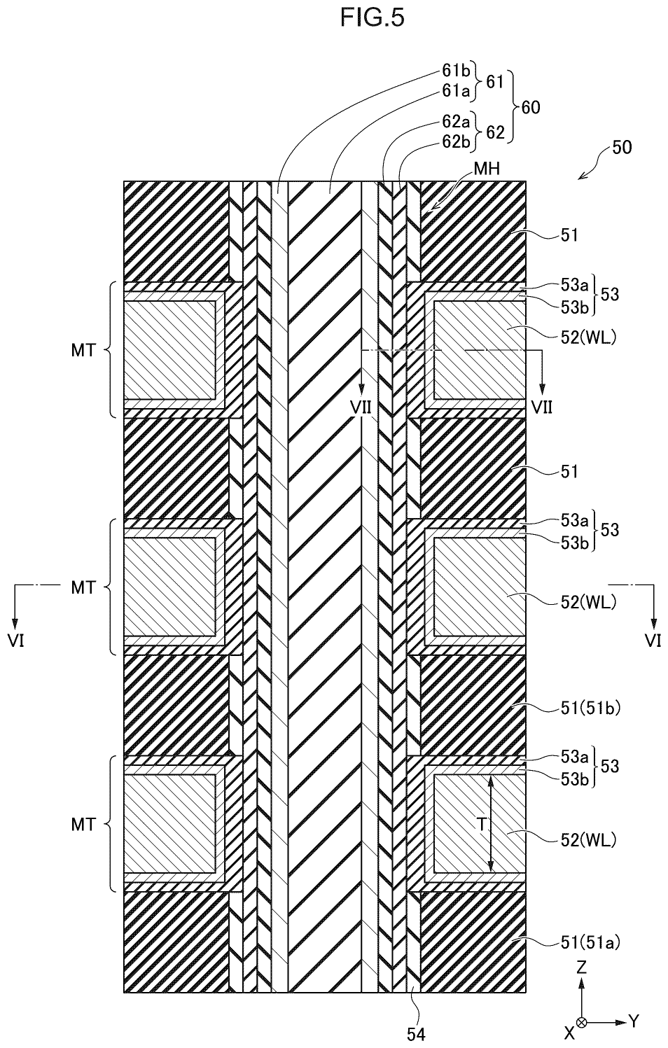

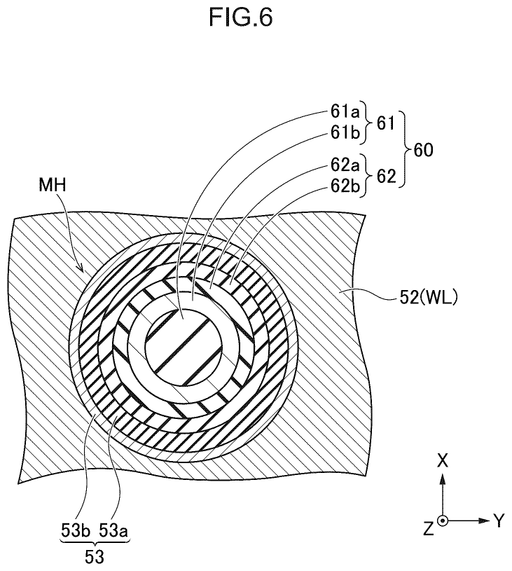

FIG. 5 shows a sectional structure of the stacked body 50 taken by cutting one of the memory pillars 60 along a plane (a Y-Z plane) passing through its center axis. FIG. 6 shows a sectional structure along a line VI-VI in FIG. 5.

As shown in FIG. 6, the memory pillars 60 each have a circular or oval sectional shape. The memory pillars 60 each include a body 61 and a film lamination 62.

The body 61 includes a core portion 61a and a semiconductor portion 61b. The semiconductor portion 61b contains a semiconductor material and is formed of, for example, a material containing amorphous silicon or a material containing polysilicon. The semiconductor portion 61b is a part at which channels of the memory cell transistors MT and the like are formed, and functions as a semiconductor channel of the present embodiment. The core portion 61a is provided inside the semiconductor portion 61b. The core portion 61a is formed of an insulating material such as silicon oxide. The body 61 may be entirely structured as the semiconductor portion 61b and no core portion 61a may be provided inside.

The film lamination 62 is in the form of a multi-layer film formed in such a position that it covers an outer periphery of the body 61. The film lamination 62 includes, for example, a tunnel insulating film 62a and a charge storage layer 62b. The tunnel insulating film 62a is provided in a position on the outer periphery of the body 61. The tunnel insulating film 62a, for example, contains silicon oxide or silicon oxide and silicon nitride. The tunnel insulating film 62a is a potential barrier between the body 61 and the charge storage layer 62b. For example, in injecting electrons from the body 61 into the charge storage layer 62b (the writing operation), the electrons pass (tunnel) through the potential barrier of the tunnel insulating film 62a. In injecting holes from the body 61 into the charge storage layer 62b (the erasure operation), the holes pass through the potential barrier of the tunnel insulating film 62a.

The charge storage layer 62b is a film formed such that it covers an outside of the tunnel insulating film 62a. The charge storage layer 62b contains, for example, silicon nitride. The charge storage layer 62b has a trap site where charges are to be trapped in the film. Portions of the charge storage layer 62b sandwiched between the conductive layers 52 and the body 61 provide the charge storage layers in which charges are accumulated, in other words, storage regions of the memory cell transistors MT. A threshold voltage of the memory cell transistors MT varies with whether or not charges are in the charge storage layer 62b or the amount of the charges.

As shown in FIG. 5, an outer peripheral surface of the conductive layers 52 is covered by a block insulating film 53. The block insulating film 53 is a film for reducing back tunneling of charges from the conductive layers 52 toward the film lamination 62. The block insulating film 53 is formed of, for example, a material containing silicon oxide and aluminum oxide.

A cover insulating film 54 is provided between the insulator layers 51 and the charge storage layer 62b. The cover insulating film 54 may be formed of, for example, a material containing silicon oxide. The cover insulating film 54 is a film for protecting the charge storage layer 62b from being etched during a replacement step of replacing sacrifice layers (sacrifice layers 55 as described later) with the conductive layers 52. For example, in a case where the replacement step is not used to form the conductive layers 52, no cover insulating film 54 may be provided.

A part of each memory pillar 60, the part being positioned inside each conductive layer 52 functions as a transistor. Specifically, in each memory pillar 60, a plurality of transistors are electrically connected in series in the longitudinal direction of the memory pillar 60. Each conductive layer 52 is connected to the gate of the corresponding transistor through the corresponding film lamination 62. The semiconductor portion 61b inside each transistor functions as a channel of the transistor.

Parts of the transistors arranged in series along the longitudinal direction of each of the memory pillars 60 function as the plurality of memory cell transistors MT shown in FIG. 3. Further, the transistors formed at both ends of the plurality of memory cell transistors MT arranged in series function as the select transistors STD and STS, respectively, shown in FIG. 3.

As shown in FIG. 4, the plurality of bit lines BL are provided above each of the memory pillars 60. The bit lines BL are each formed in the form of a linear wiring line extending in the X direction. The bit lines BL are disposed side by side in the Y direction. Upper ends of the memory pillars 60 are connected to the plurality of bit lines BL through contacts Cb. With such a structure, the semiconductor portion 61b of the memory pillars 60 are electrically connected to the bit lines BL.

The stacked body 50 is divided into a plurality of portions by a slit ST. The slit ST is a linear groove formed to extend along the Y direction in FIG. 4, and is formed deep sufficient to reach, for example, the semiconductive layer 42.

An upper portion of the stacked body 50 is divided by a slit SHE. The slit SHE is a shallow groove formed such that it extends in the Y direction. The slit SHE is formed deep sufficient to divide only the conductive layer 52 of the plurality of conductive layers 52 that is provided as the select gate line SGD.

The film lamination 62 is removed at a lower end portion of the memory pillars 60. Accordingly, a lower end portion of the semiconductor portion 61b is connected to the semiconductive layer 42. With such a structure, the semiconductive layer 42, which functions as the source line SL, is electrically connected to the channels of the transistors.

As described above, the semiconductor storage device 10 according to the present embodiment includes a plurality of insulator layers 51 corresponding to insulating films, and conductive layers 52 each formed of, for example, tungsten films and provided between the plurality of insulator layers 51 (hereinafter, the conductive layers 52 are also referred to as tungsten films 52). In other words, the semiconductor storage device 10 according to the present embodiment includes one insulating film (first insulating film in the present embodiment) 51a among a plurality of insulator layers 51, another insulating film (second insulating film in the present embodiment) 51b separated from the one insulating film in the Z-axis direction (Z direction), and a tungsten film 52 provided between the one insulating film 51a and the other insulating film 51b. In the semiconductor storage device 10 according to the present embodiment, the tungsten film 52, which has a crystal particle (or crystal particles), is provided so that the relation of APS/T≤2 is satisfied where T represents the thickness of the tungsten film 52 and APS represents the average particle size of the crystal particle (or the crystal particles) of the tungsten film 52. In the present embodiment, the thickness T of the tungsten film 52 is the thickness of the tungsten film 52 in the Z-axis direction as described later. As shown in FIG. 5, in the semiconductor storage device 10 according to the present embodiment, a plurality of insulating films 51 and a plurality of tungsten films 52 are stacked in the Z-axis direction in the order of an insulating film 51 (first insulating film 51a), a tungsten film 52 (in FIG. 5, a tungsten film 52 between the first insulating film 51a and the second insulating film 51b), an insulating film 51 (first insulating film 51b), a tungsten film 52 (in FIG. 5, a tungsten film 52 provided on the upper side of the second insulating film 51b in the Z-axis direction) . . . . Thus, the thickness T of each tungsten film 52 in the present embodiment is the thickness of the tungsten film 52 in the Z-axis direction corresponding to a direction (in the present embodiment, first direction) from an insulating film 51 (for example, the first insulating film 51a) to another insulating film 51 (for example, the second insulating film 51b). In the example shown in FIG. 5, one insulating film 51a, a tungsten film 52, and the other insulating film 51b are stacked in the stated order with a block insulating film 53 and the like interposed therebetween, the block insulating film 53 including a silicon oxide film 53a and an aluminum oxide film 53b to be described later. In the present embodiment, the first direction may be a vertical direction against the substrate 40.

The present inventors have found a problem that, in a manufacturing step of a semiconductor storage device, a silicon wafer of a semiconductor substrate used as a substrate potentially warps downward after tungsten films are deposited as word lines. The problem of warping of a silicon wafer is thought to become more significant along with recent increase in the number of stacked layers in a semiconductor storage device.

Through diligent consideration, the present inventors have found that stress as a factor of warping can be reduced by providing tungsten films in a relatively small particle size. It is thought that, with the small particle size, the imbalance of the direction of stress is reduced and stress distribution is averaged. According to the consideration of the present inventors, it was found that stress can be excellently reduced when the relation of APS/T≤2 is satisfied where T represents the thickness of each tungsten film and APS represents the average particle size of the crystal particle(s) of the tungsten film as described above.

Moreover, although stress can be reduced when APS/T≤2 is satisfied, it was found that a more significant effect can be obtained, for example, when APS/T≤1 is satisfied. In addition, it was found that an effect of reducing stress as a factor of warping of a tungsten film can be obtained when 0.3 APS/T is satisfied as well. Each tungsten film 52 may be provided such that, for example, the average particle size APS of the crystal particle(s) of the tungsten film 52 is 120 nm or less, preferably 80 nm or less, and more preferably 50 nm or less or 40 nm or less. Each tungsten film 52 may be provided such that the film thickness T is 60 nm or less, preferably 40 nm or less, and more preferably 25 nm or less or 20 nm or less. Each tungsten film 52 is preferably formed such that APS/T≤2 is satisfied in such ranges of the average particle size APS and the film thickness T. For example, when each tungsten film 52 is provided such that the film thickness T is 60 nm, the average particle size of tungsten crystal particles included in the tungsten film 52 may be 120 nm or less to satisfy APS/T≤2, or the average particle size is more preferably 60 nm or less (for example, 50 nm) to satisfy APS/T≤1. Similarly, when each tungsten film 52 is provided such that the film thickness T is 40 nm, the average particle size of tungsten crystal particles included in the tungsten film 52 may be 80 nm or less, or the average particle size is more preferably 40 nm or less. When each tungsten film 52 is provided such that the film thickness T is 25 nm, the average particle size of tungsten crystal particles included in the tungsten film 52 may be 50 nm or less, or the average particle size is more preferably 25 nm or less. When each tungsten film 52 is provided such that the film thickness T is 20 nm, the average particle size of tungsten crystal particles included in the tungsten film 52 may be 40 nm or less, or the average particle size is more preferably 20 nm or less. Alternatively, each tungsten film 52 may be formed such that 0.3 APS/T is satisfied as described above. For example, when each tungsten film 52 is provided such that the film thickness T is 60 nm, the average particle size of tungsten crystal particles included in the tungsten film 52 may be 20 nm or more.

As shown in FIG. 5, the film thickness T in the present embodiment means the thickness of each tungsten film 52 in the Z-axis direction after deposition. As described later, in a manufacturing process of each tungsten film 52 of the present embodiment, deposition is performed so that tungsten crystal included in the tungsten film grows in the upward and downward directions along the Z-axis direction, and thus the film thickness T of the tungsten film 52 may be adjusted through a thickness corresponding to the growth in deposition. Thus, for example, when a tungsten film 52 of the film thickness T is to be formed, adjustment may be performed in a deposition step so that the thickness of the tungsten film grown in the upward direction along the Z-axis direction and the thickness of the tungsten film grown in the downward direction along the Z-axis direction each become, for example, T/2 approximately. For example, when a tungsten film that functions as a word line having a film thickness of 60 nm is to be formed, the tungsten film may be grown by 30 nm in the upward and downward directions along the Z-axis direction, respectively. Alternatively, deposition may be performed so that the tungsten film grows in any one of the upward direction and the downward direction along the Z-axis direction, and in this case as well, the same effect as that of the present embodiment is achieved by depositing the tungsten film so that APS/T described above becomes 2 or less. Specifically, for example, in a deposition process of growing a tungsten film having a film thickness of 60 nm in the upward direction along the Z-axis direction, deposition may be performed so that the average particle size of tungsten crystal particles included in the tungsten film becomes 120 nm or less. More preferably, the tungsten film 52 may be deposited in the upward direction along the Z-axis direction so that the average particle size of tungsten crystal particles becomes 60 nm or less.

In the present embodiment, the film thickness T of a tungsten film 52 corresponds to the thickness of a conductive layer 52. For example, as indicated by reference sign T in FIG. 5, the thickness T of a tungsten film 52 may be the size of the conductive layer 52 in the Z-axis direction when the memory pillar 60 is viewed along a plane (YZ plane) passing through the central axis. The particle size of a tungsten crystal particle included in a tungsten film 52 may be measured by a well-known method. For example, the particle size of a crystal particle may be acquired by acquiring a microscope image (including an optical microscope image or a scanning or transmissive electron microscope image) of a section (for example, section parallel to the XZ plane in FIG. 5) of the conductive layer 52 and measuring the maximum dimension of the crystal particle at the section by using the microscope image. Alternatively, the particle size may be measured by, for example, an electron backscatter diffraction (EBSD) method. For example, in a case in which the cross-sectional area of the crystal particle can be measured, the particle size may be acquired by, for example, converting the cross-sectional area of the crystal particle into the diameter of a precise circle approximating the section of the crystal particle, the cross-sectional area being measured by performing image analysis based on a crystal particle map obtained by the EBSD method. For example, when S represents the cross-sectional area of the crystal particle and r represents the radius of the crystal particle, the radius r may be calculated based on the relation of S=πr² and twice of the radius r may be obtained as the particle size. Alternatively, the average particle size of crystal particles in the conductive layer 52 may be calculated by, for example, calculating the average value of measured particle sizes. Alternatively, the average particle size may be acquired by calculating a weighted average of acquired particle sizes of individual crystal particles. The weighted average may be calculated by, for example, calculating the cross-sectional area of each individual crystal particle in addition to the particle size in the microscope image of the section of the tungsten film 52 and dividing the sum of the product of the particle size and cross-sectional area of an individual crystal particle for all crystal particles by the sum of the cross-sectional area for all crystal particles.

In the present embodiment, a particle size at a section orthogonal to or substantially orthogonal to the film thickness T (deposition direction) may be acquired as the particle size of a crystal particle in the tungsten film. For example, in FIG. 5, when the film thickness T is the size of the conductive layer 52 in the Z-axis direction, a particle size at a section parallel to the XY plane may be acquired as the particle size of a crystal particle.

### 1.5 Semiconductor Device Manufacturing Method

A method of manufacturing the semiconductor device 10 according to the present embodiment will be described below. The method of manufacturing the semiconductor storage device 10 according to the present embodiment includes a step of providing an insulating film 51 (insulator layer 51), a step of providing a barrier metal film 56 on the insulating film 51, a step of providing a new creation film 57 of tungsten on the barrier metal film 56, a step of providing a first tungsten film 52a having a thickness T1 on the new creation film 57, a step of annealing at least the new creation film 57 and the first tungsten film 52a, and a step of providing a tungsten film 52 having the thickness T and the average particle size APS, where APS/T≤2 is satisfied, by providing a second tungsten film 52b having a thickness T2 larger than the thickness T1 on the annealed first tungsten film 52a. The thickness T of a tungsten film 52 in the present embodiment is the thickness of the tungsten film 52 in the Z-axis direction as described above with reference to, for example, FIG. 5. In the method of manufacturing the semiconductor storage device 10 according to the present embodiment, an insulating film 51 (in the present embodiment, the first insulating film 51a), a tungsten film 52, and another insulating film 51 (in the present embodiment, the second insulating film 51b) are stacked in the stated order with the barrier metal film 56, the new creation film 57, and the like interposed therebetween, and the thickness T of the tungsten film 52 is a thickness in the Z-axis direction corresponding to the direction (in the present embodiment, first direction) from the first insulating film 51a to the second insulating film 51b.

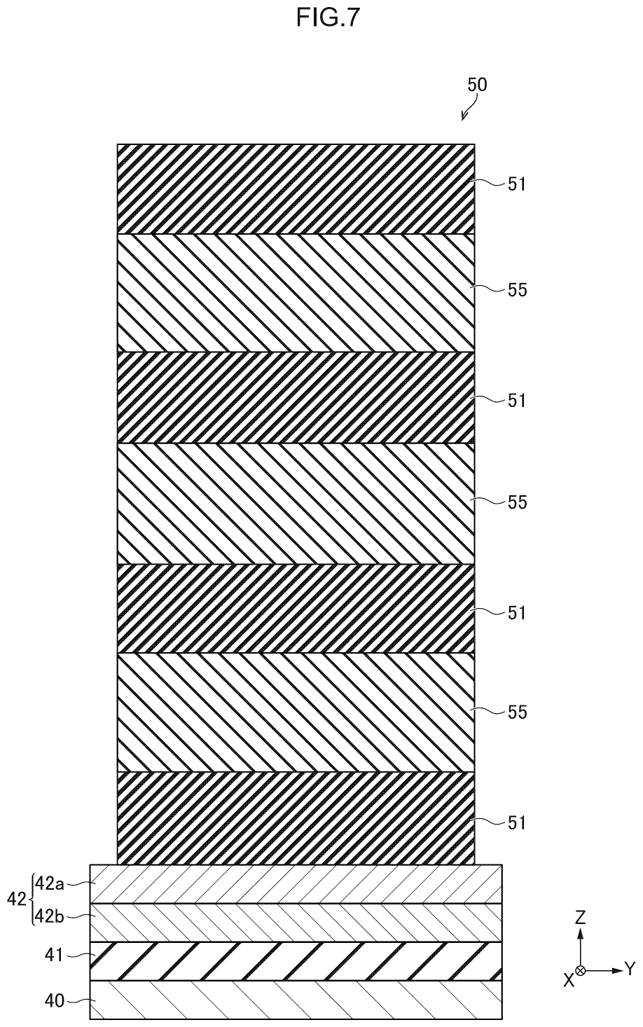

The method of manufacturing the semiconductor device 10 according to the present embodiment will be described below in detail with reference to FIGS. 7 to 16. FIGS. 7 to 16 are each a cross-sectional view schematically showing part of a manufacturing step of the semiconductor device 10 according to the present embodiment. As shown in FIG. 7, first, the insulator layer 41 and the semiconductive layer 42 are formed on the substrate 40, and the stacked body 50 alternately including a plurality of insulator layers 51 and a plurality of sacrifice layers 55 is formed on the semiconductive layer 42. The substrate 40 is a plate-shaped member having a flat surface on the Z-axis direction side and is, for example, a semiconductor substrate such as a silicon substrate. The insulator layer 41 may be formed of an insulating material such as silicon oxide. The semiconductive layer 42 may be formed of, for example, a material containing silicon, such as polycrystalline silicon doped with impurities. Each insulator layer 51 included in the stacked body 50 corresponds to an insulating film in the present embodiment and is formed of a material containing, for example, silicon oxide. Each insulator layer 51 may be, for example, a TEOS layer. The TEOS layer is a silicon oxide layer made of tetra ethyl ortho silicate (TEOS) and may be formed by, for example, the CVD method. The sacrifice layers 55 are replaced with conductive layers 52 in a later replacement step. The sacrifice layers 55 may be formed of, for example, a material containing silicon nitride by the CVD method. After the sacrifice layers 55 are replaced with conductive layers 52 in the later step, each insulator layer 51 is disposed between conductive layers 52 adjacent to each other and electrically insulates the conductive layers 52. Although FIG. 7 schematically shows a case in which four insulator layers 51 and three sacrifice layers 55 are stacked, the number of stacked layers in the stacked body 50 are not limited thereto. For example, the number of stacked insulator layers 51 and the number of stacked sacrifice layers 55 (conductive layers 52 that function as word lines and are formed after the sacrifice layers 55 are removed as described later) may be three or fewer or may be five or more. In particular, 100 or more conductive layers 52 are stacked in a semiconductor storage device including an increased number of stacked layers like a recent semiconductor storage device, and the present embodiment is also applicable to such a semiconductor storage device including an increased number of stacked layers. Moreover, according to the present embodiment as described later, it is possible to efficiently proceed the process of manufacturing a semiconductor storage device including an increased number of stacked layers, in particular.

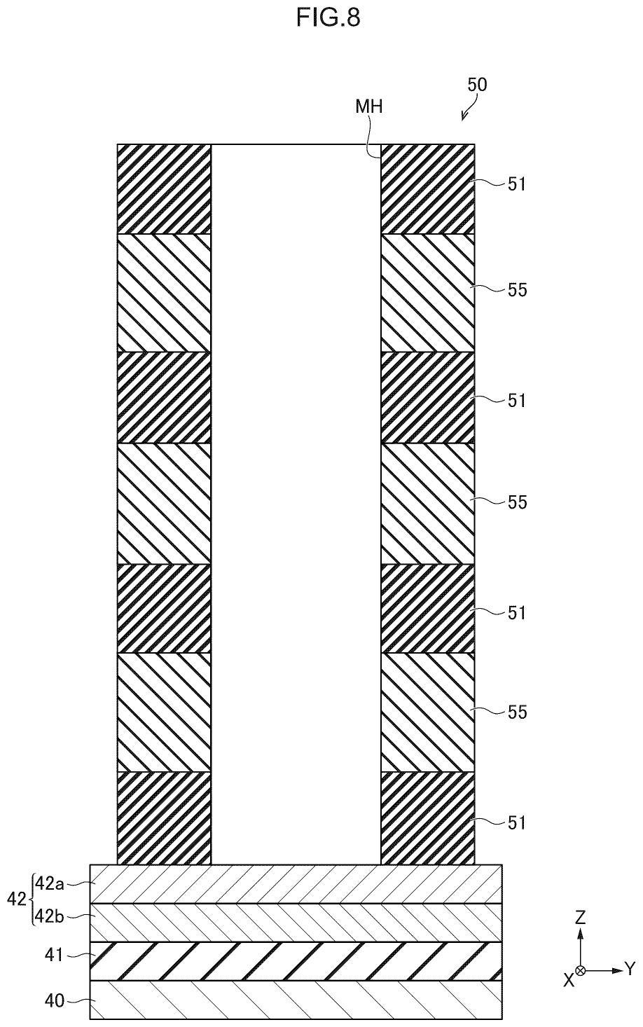

Subsequently, a memory hole MH extending (penetrating) through the insulator layer 41, the semiconductive layer 42, and the stacked body 50 is formed in the stacked body 50 as shown in FIG. 8. The memory hole MH may be formed by anisotropic etching such as reactive ion etching (RIE).

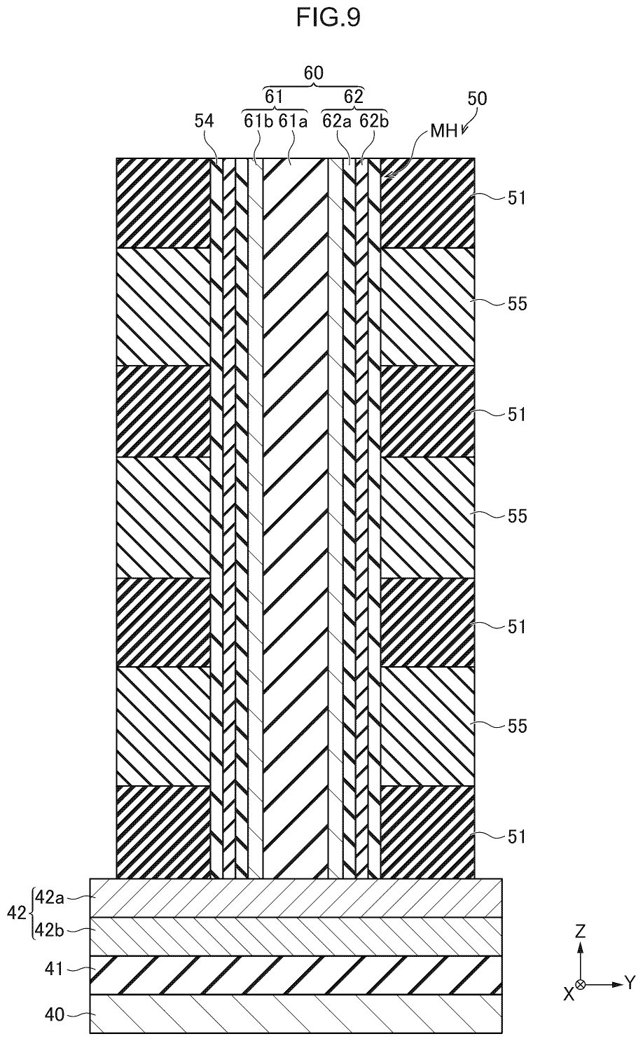

Subsequently, the cover insulating film 54, the film lamination 62, and the body 61 are formed in the stated order on the inner surfaces of the insulator layers 51 and the conductive layers 52 in the memory hole MH as shown in FIG. 9. The cover insulating film 54 may be formed of, for example, a material containing silicon oxide. The charge storage layer 62b and the tunnel insulating film 62a are formed as the film lamination 62 on the inner side of the cover insulating film 54. The charge storage layer 62b may be formed of, for example, a material containing silicon nitride. The tunnel insulating film 62a may be formed of, for example, a material containing silicon oxide or a material containing silicon oxide and silicon nitride. The semiconductor portion 61b and the core portion 61a are formed as the body 61 on the inner side of the tunnel insulating film 62a. The semiconductor portion 61b contains, for example, a semiconductor material and may be formed of, for example, a material containing amorphous silicon. The core portion 61a may be formed of an insulating material such as silicon oxide.

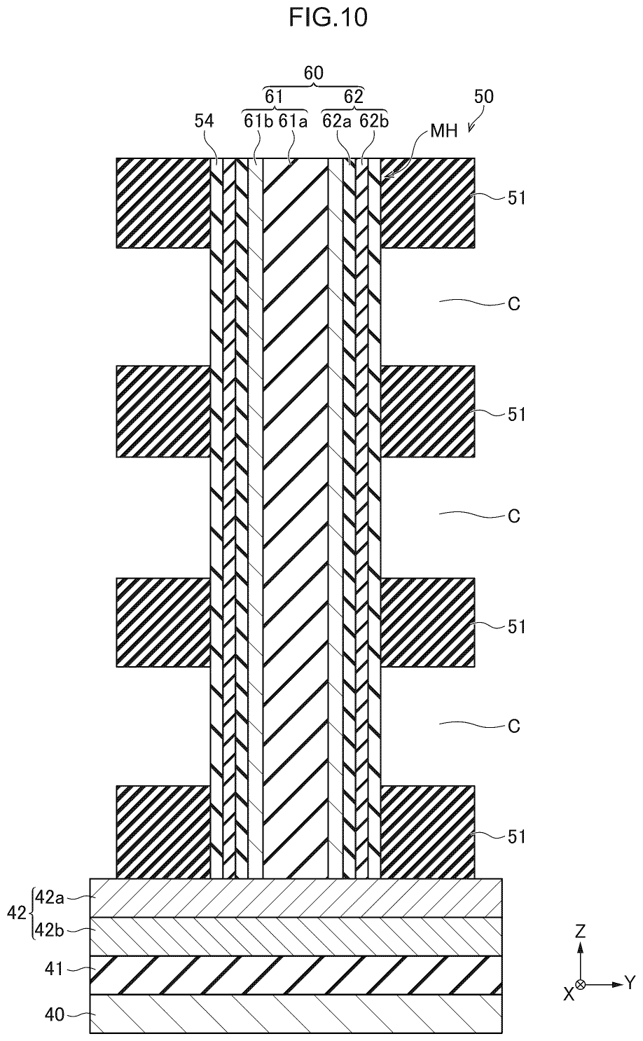

Subsequently, non-shown grooves are formed in the stacked body 50, and then the sacrifice layers 55 are removed by using the grooves. The grooves may be formed in the depth direction (Z-axis direction) up to the semiconductive layer 42 by, for example, RIE. The sacrifice layers 55 may be removed by, for example, wet etching through the grooves by using drug solution such as phosphoric acid. Accordingly, a void space C is formed between insulator layers 51 adjacent to each other as shown in FIG. 10. Surfaces of the insulator layers 51 in the Z-axis direction and a surface (surface in the Y-axis direction) of the cover insulating film 54 are exposed in each void space C as shown in FIG. 10. Since the cover insulating film 54 is provided as described above, the charge storage layer 62b is protected from etching in the step of removing the sacrifice layers 55.

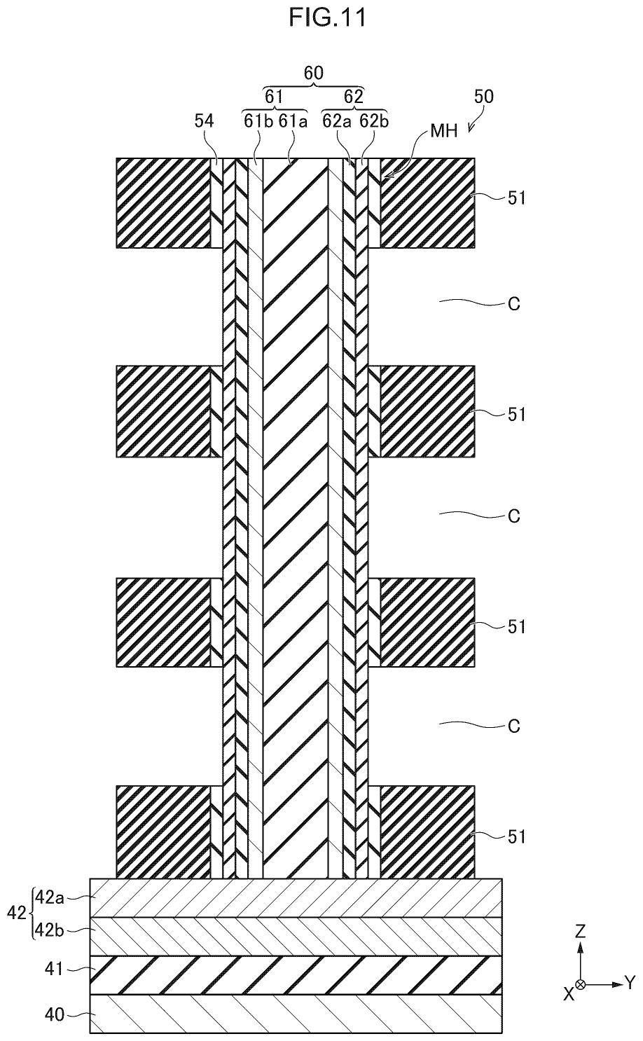

Subsequently, the cover insulating film 54 exposed in each void space C is removed to expose a surface of the charge storage layer 62b in the Y direction as shown in FIG. 11.

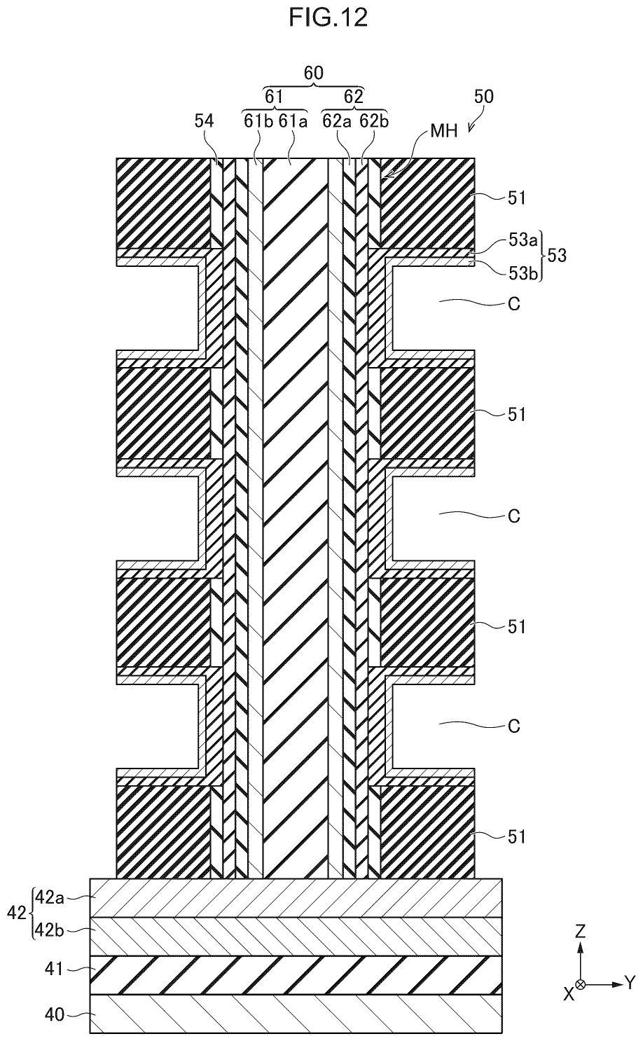

Subsequently, the silicon oxide film 53a and the aluminum oxide film 53b are formed in the stated order on the surfaces of the insulator layers 51 in the Z-axis direction and the surface of the charge storage layer 62b in the Y direction. Accordingly, the block insulating film 53 is formed in each void space C as shown in FIG. 12. The silicon oxide film 53a and the aluminum oxide film 53b may be formed by, for example, a thermal CVD method or an atomic layer deposition (ALD) method.

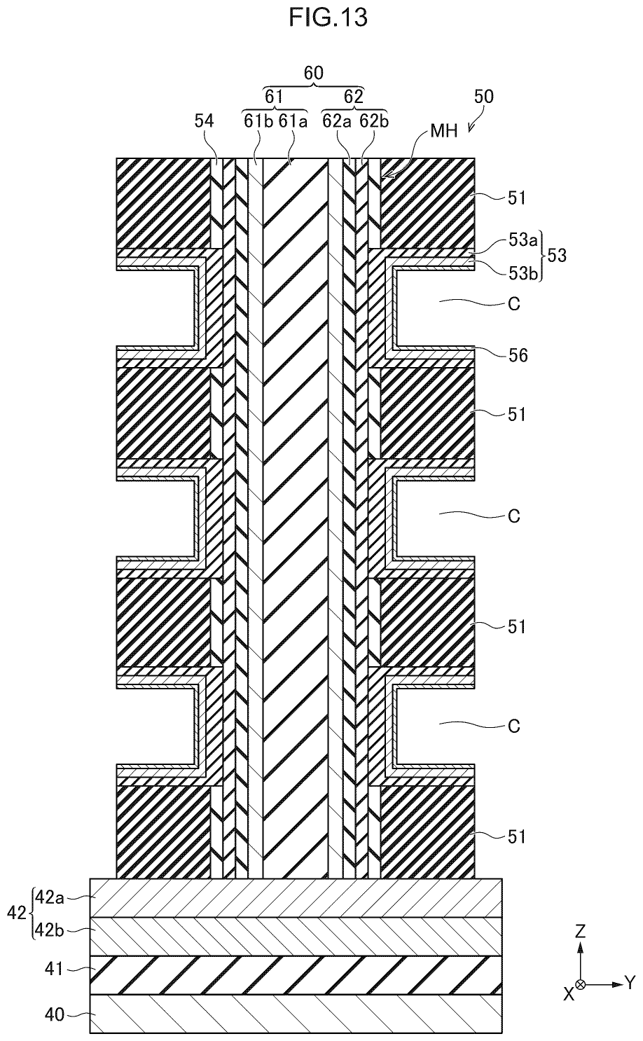

Subsequently, the barrier metal film 56 is formed on surfaces (surfaces in the Z-axis direction and the Y direction) of the aluminum oxide film 53b as shown in FIG. 13. The barrier metal film 56 may be formed of, for example, a material containing titanium nitride (TiN) by the CVD method or the ALD method.

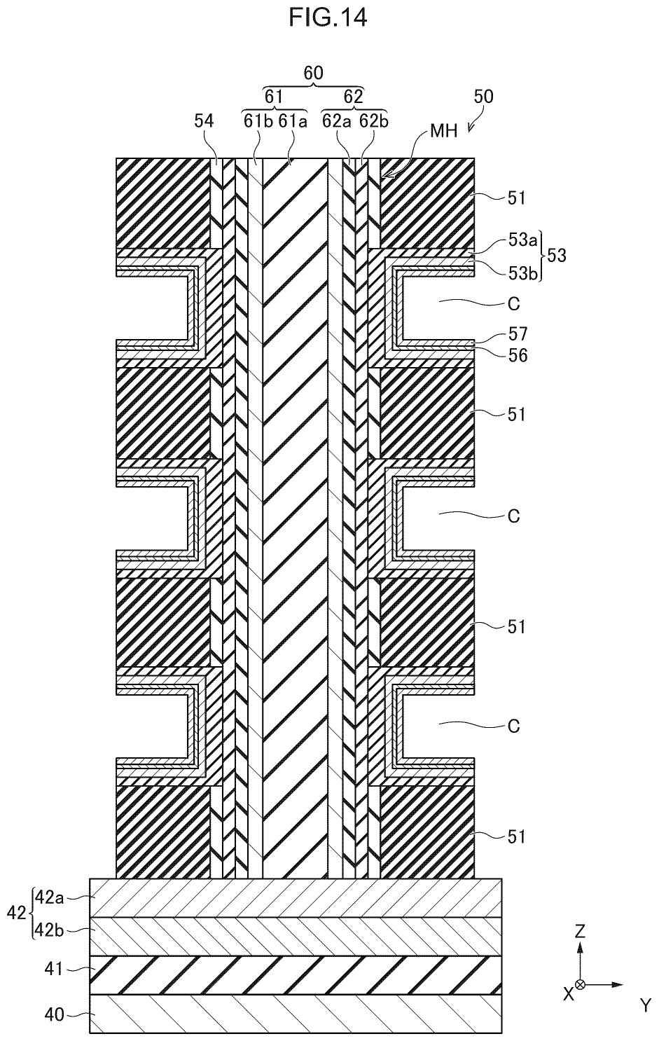

Subsequently, the new creation film 57 as an initial tungsten film is formed on surfaces (surfaces in the Z-axis direction and the Y direction) of the barrier metal film 56 as shown in FIG. 14. The new creation film 57 may be formed by the CVD method using, for example, treatment gas containing tungsten hexafluoride (WF₆) gas and diborane (B₂H₆) gas as primary components. The new creation film 57 may be formed to have, for example, a thickness of 1 nm to 5 nm inclusive. The new creation film 57 is preferably formed to have, for example, a thickness of 2 nm to 4 nm inclusive.

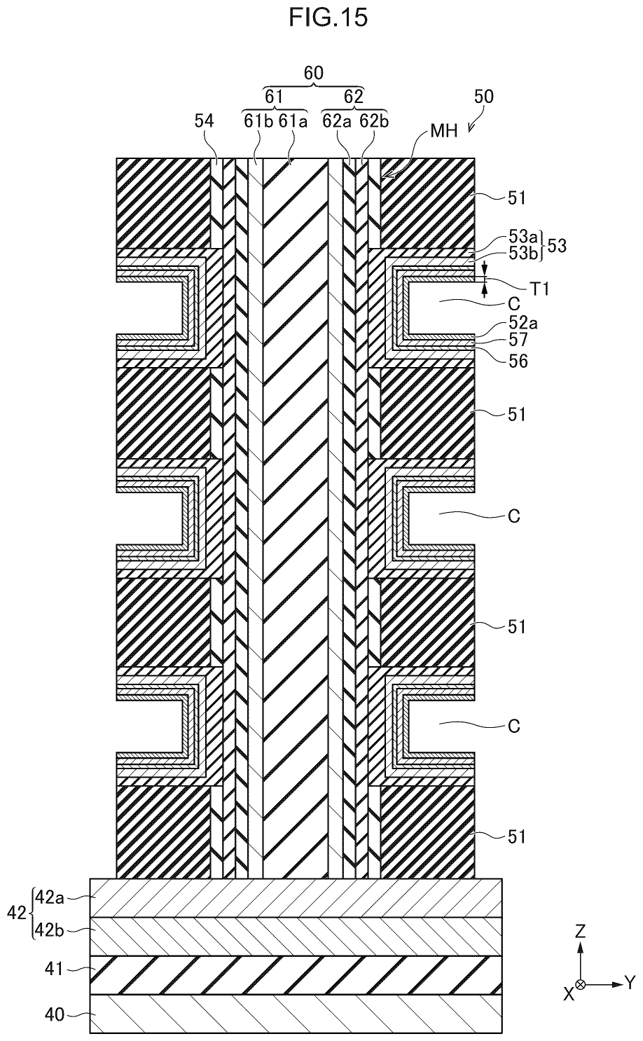

Subsequently, the first tungsten film 52a is formed on surfaces (surfaces in the Z-axis direction and the Y direction) of the new creation film 57 to have a thickness T1 as shown in FIG. 15. The first tungsten film 52a may be formed by the CVD method using, for example, treatment gas containing tungsten hexafluoride (WF₆) gas as deposition gas and hydrogen (H 2) gas as reduction gas. The first tungsten film 52a may be formed to have, for example, a thickness T1 of 0.1 nm to 5 nm inclusive. The thickness of the first tungsten film 52a is preferably, for example, 0.5 nm to 3 nm inclusive.

Subsequently, a treatment container used in a deposition step as necessary is opened to the atmosphere, and then the first tungsten film 52a is subjected to anneal treatment by rapid thermal treatment, for example, a rapid thermal annealing (RTA) method. The anneal treatment may be performed, for example, in nitrogen (N₂) gas or oxygen (O₂) gas atmosphere in a temperature range of 600° C. to 900° C. inclusive for a time of 5 seconds to 20 seconds inclusive.

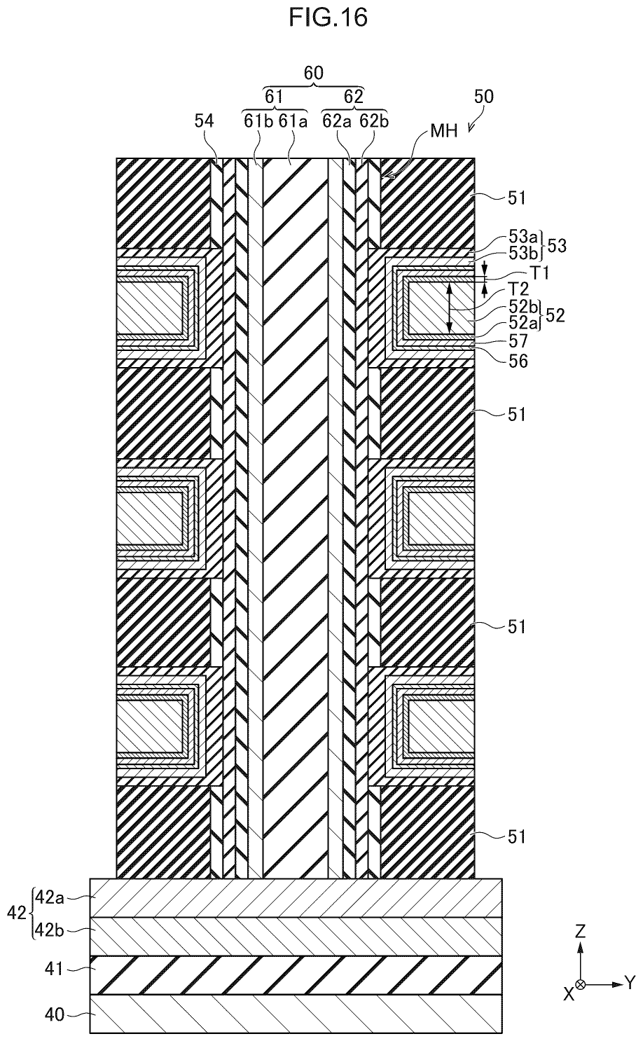

In addition, the treatment container used in a deposition step as necessary is opened to the atmosphere again, and then the second tungsten film 52b is formed on surfaces (surfaces in the Z-axis direction and the Y direction) of the first tungsten film 52a to have a thickness T2 larger than the thickness T1 of the first tungsten film 52a as shown in FIG. 16. The second tungsten film 52b may be formed by, for example, the same method as the first tungsten film 52a and may be formed by the CVD method using treatment gas containing tungsten hexafluoride (WF₆) gas as deposition gas and hydrogen (H₂) gas as reduction gas. The second tungsten film 52b is formed such that the relation of APS/T≤2 is satisfied where T represents the thickness of the tungsten film 52 (specifically, the sum of twice of the thickness T1 of the first tungsten film 52a and the thickness T2 of the second tungsten film 52b) and APS represents the average particle size of the crystal particle(s) of the tungsten film 52. As described above, the tungsten film 52 thus formed corresponds to a conductive layer 52 in the present embodiment and functions as a word line. The conductive layer 52 may be formed of, for example, a material containing molybdenum in another embodiment. Another step may be performed as necessary after the tungsten film 52 is formed. For example, anneal treatment may be performed in addition when needed. In the present embodiment, the second tungsten film 52b is formed by growing tungsten crystal in the upward direction along the Z-axis direction from the upper surface of the first tungsten film 52a in the Z-axis direction and growing tungsten crystal in the downward direction along the Z-axis direction from the lower surface of the first tungsten film 52a in the Z-axis direction. The second tungsten film 52b of the thickness T2 may be formed by depositing a tungsten film to have a thickness of T2/2 in the upward direction along the Z-axis direction from the upper surface of the first tungsten film 52a in the Z-axis direction and a thickness of T2/2 in the downward direction along the Z-axis direction from the lower surface thereof in the Z-axis direction.

In this manner, the semiconductor device 10 of the present embodiment is formed.

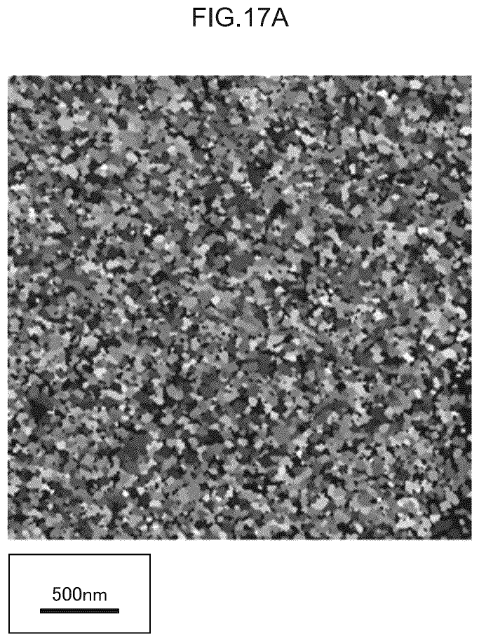

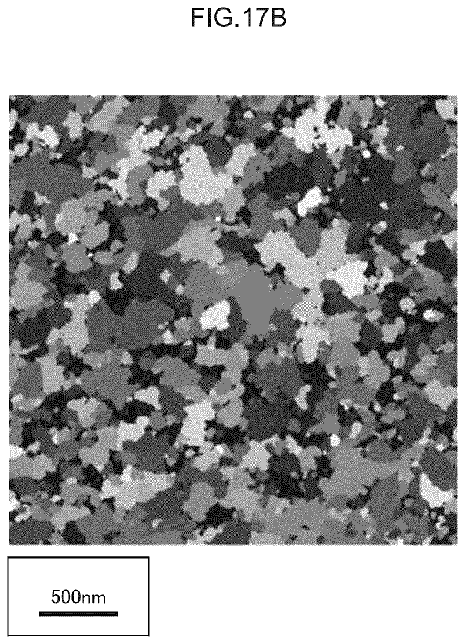

The thickness T and the average particle size APS of the crystal particle(s) of each tungsten film 52 in the semiconductor device 10 according to the present embodiment will be described below with reference to FIGS. 17A and 17B.

FIG. 17A shows a crystal particle map of a section of a conductive layer 52 in the semiconductor device (semiconductor storage device) 10 of an example according to the present embodiment, the crystal particle map being obtained by the EBSD method. FIG. 17B shows a crystal particle map of a section of a conductive layer in a semiconductor storage device (hereinafter, also referred to as a semiconductor device 200) of a comparative example. The semiconductor device 200 of the comparative example was manufactured by a manufacturing step different from the manufacturing step of the semiconductor device 10 of the example according to the present embodiment, and the difference is such that the tungsten film 52 is formed not by a step of forming the first tungsten film 52a having a small thickness and then forming the second tungsten film 52b after performing thermal treatment like the manufacturing step of the semiconductor device 10 according to the present embodiment described above. Specifically, the semiconductor device 200 of the comparative example is formed by, for example, forming a barrier metal film (hereinafter, also referred to as a barrier metal film 256) on an insulator layer (hereinafter, also referred to as an insulator layer 251) as described above, forming a new creation film (hereinafter, also referred to as a new creation film 257), and then forming a tungsten film (hereinafter, also referred to as a tungsten film 252) while maintaining a vacuum state, and subsequently performing anneal treatment.

As shown in FIGS. 17A and 17B, the particle size in the semiconductor device 10 of the example according to the present embodiment was reduced as compared to the particle size in the semiconductor device 200 of the comparative example. The average particle size (in this example, the weighted average particle size described above) was calculated by measuring the particle size based on the crystal particle maps, and the average particle size of tungsten crystal particles of the tungsten film 52 in the semiconductor device 10 of the example according to the present embodiment and the average particle size of tungsten crystal particles of the tungsten film 252 in the semiconductor device 200 of the comparative example were 50 nm and 170 nm, respectively.

Specifically, through diligent consideration, the present inventors succeeded in reducing the particle size of tungsten crystal particles included in the tungsten film 52 by depositing the new creation film 57, forming the first tungsten film 52a having a relatively small thickness, performing thermal treatment, and then forming the second tungsten film 52b in the above-described manufacturing step. It is thought that, since the second tungsten film 52b was formed after the first tungsten film 52a having a relatively small thickness was formed, the particle size of tungsten crystal particles included in the second tungsten film 52b formed after formation of the first tungsten film 52a in which the particle size of tungsten crystal particles was relatively small was affected by tungsten crystal of the first tungsten film 52a formed in the previous step, and accordingly, the particle size of crystal particles in the second tungsten film 52b was relatively small. Moreover, in the present embodiment, after the new creation film 57 is formed, the first tungsten film 52a is formed and thermal treatment (rapid thermal treatment) is provided before the second tungsten film 52b is formed. It is thought that the particle size of tungsten crystal in the first tungsten film 52a was reduced because, through the rapid thermal treatment, tungsten in the amorphous state in the new creation film 57 and the first tungsten film 52a became polycrystalline as the new creation film 57 and the first tungsten film 52a were integrated. It is thought that since the second tungsten film 52b formed thereafter was likely to be affected by the material, crystalline nature, and the like of the first tungsten film 52a, the second tungsten film 52b was deposited and constituted by tungsten crystal having a small particle size due to influence of tungsten crystal having a small particle size included in the first tungsten film 52a.

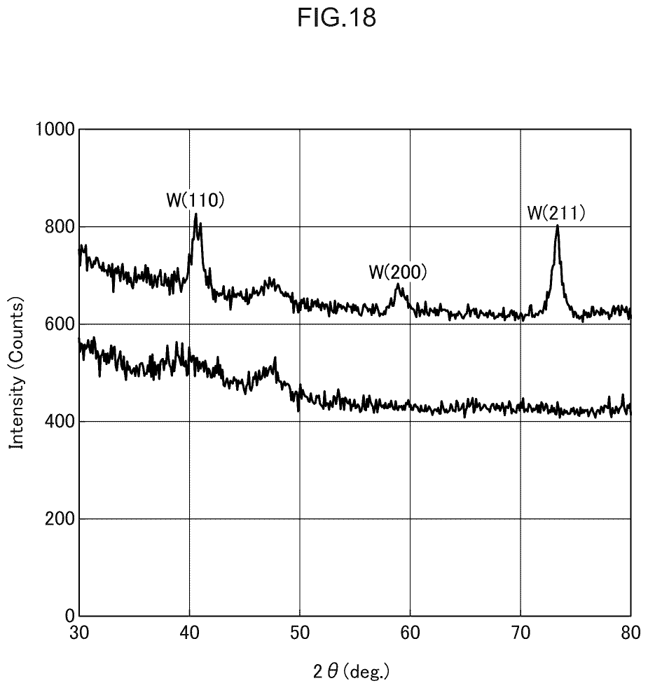

In addition, crystal orientation was measured to check influence of the manufacturing step of the semiconductor device 10 according to the present embodiment on the crystalline nature of tungsten. FIG. 18 shows diffracted X-ray spectra of the semiconductor device 10 of the example according to the present embodiment and the semiconductor device 200 of the comparative example. In FIG. 18, measured diffracted X-ray intensity (the vertical axis; the number “Counts” of diffracted X-rays acquired by a detector in a predetermined time) is plotted against a diffraction angle 20 (the horizontal axis) for each of the semiconductor device 10 of the example according to the present embodiment and the semiconductor device 200 of the comparative example. The diffracted X-ray intensity shown in FIG. 18 was measured by an X-ray diffraction (XRD) method by using SmartLab (3-kW encapsulated pipe type) manufactured by Rigaku Corporation.

As shown in FIG. 18, for a tungsten film in the semiconductor device 10 of the example according to the present embodiment, for example, three local maximum values corresponding to (110), (200), and (211) planes, respectively, were observed (denoted by W(110), W(200), and W(211), respectively, in FIG. 18), and peaks at orientations (110) and (211) were strongly observed, in particular, as compared to the semiconductor device 200 of the comparative example. Moreover, as shown in FIG. 18, almost no peak was observed at (211), in particular, for the semiconductor device 200 of the comparative example, but a strong peak was observed at (211) in the semiconductor device 10 of the example according to the present embodiment. This is thought to be because, since the tungsten film 52 was formed so that the particle size of tungsten crystal included in the tungsten film 52 was smaller in the semiconductor device 10 of the example according to the present embodiment, orientation was relatively randomized and peaks became likely to be observed not only in the primary direction (110) but also in another direction such as (211).

It was found that, according to the present embodiment, increase of the specific resistance value of a word line in the semiconductor device 10 is reduced as described below. Typically in a semiconductor storage device, the resistance of a word line is preferably low. For example, when a word line is provided as a tungsten film to reduce the resistance of the word line, it is thought that the word line is preferably provided such that the particle size of tungsten crystal particles included in the tungsten film is large. However, according to consideration by the present inventors, it was thought that warping of a silicon wafer increases along with increase of the particle size of tungsten crystal particles.

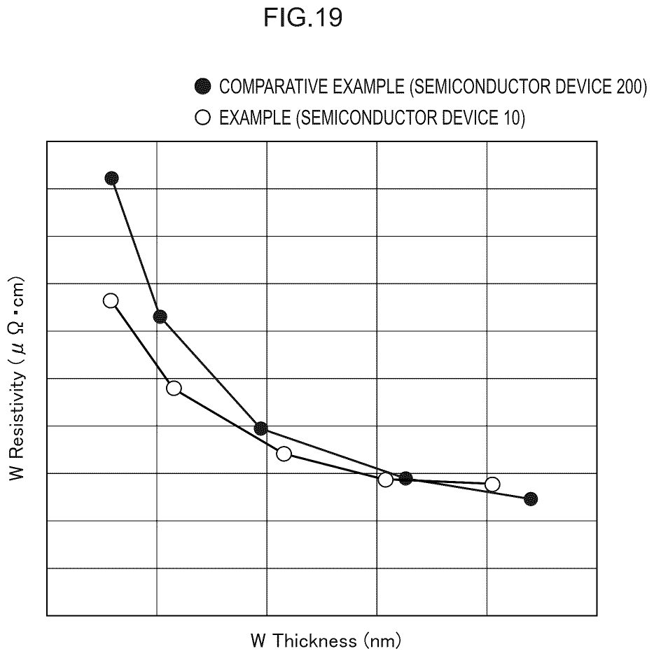

According to the present embodiment, the specific resistance of a word line in the semiconductor device 10 can be decreased. FIG. 19 shows a graph of change in the specific resistance value of a word line in the thickness direction. As shown in FIG. 19, such a result was obtained that the specific resistance value of a word line has no significant difference in the thickness direction between the semiconductor device 10 of the example according to the present embodiment and the semiconductor device 200 of the comparative example. Specifically, despite a concern on the probability of specific resistance increase due to reduction of the particle size of tungsten crystal particles included in the tungsten film 52 in the semiconductor device 10 of the example according to the present embodiment, the tungsten film 52 could be formed without increase in the specific resistance value as compared to a case of the semiconductor device 200 of the comparative example because the process of manufacturing the semiconductor device 10 according to the present embodiment was employed. The specific resistance of the tungsten film 52 of the example and the specific resistance of the tungsten film 252 of the comparative example may be measured by a well-known method such as a four-terminal method.

According to consideration by the present inventors, it is thought that the surface roughness of the tungsten film 252 is likely to be large when the particle size of tungsten crystal particles in the tungsten film 252 is relatively large as in the semiconductor device 200 of the comparative example. In a formation process of the tungsten film 252, the tungsten film 252 is formed such that tungsten crystal particles grow in the upward and downward directions along the Z-axis direction on the upper and lower surfaces, respectively, of the new creation film 257 in the Z-axis direction, the new creation film 257 being formed on the inner side of a void space (corresponding to a void space C formed in the manufacturing step of the semiconductor device 10 according to the present embodiment), and the surface of a tungsten crystal layer growing in the upward direction along the Z-axis direction and the surface of a tungsten crystal layer growing in the downward direction along the Z-axis direction approach each other. It is thought that the surface roughness of a tungsten crystal layer becomes large as the particle size of tungsten crystal included in the tungsten crystal layer becomes relatively large, and thus it is thought that a gap is likely to be generated between the surface of the tungsten crystal layer growing in the upward direction along the Z-axis direction and the surface of the tungsten crystal layer growing in the downward direction along the Z-axis direction. Since such a gap is generated between the surface of the tungsten crystal layer growing in the upward direction along the Z-axis direction and the surface of the tungsten crystal layer growing in the downward direction along the Z-axis direction, it is thought that the gap is potentially generated, for example, in a region near the center of the tungsten film 252 in the Z-axis direction, in particular. Furthermore, it is also thought that, since the surface roughness of the tungsten film is large, an opening part of the gap generated between the surface of the tungsten film of tungsten crystal growing in the upward direction along the Z-axis direction and the surface of the tungsten film of tungsten crystal growing in the downward direction along the Z-axis direction is blocked before deposition of the tungsten film 252 is completed, and as a result, tungsten hexafluoride (WF₆) gas used as deposition gas cannot flow into the gap and the deposition cannot be sufficiently performed. Accordingly, it is thought that the amount of tungsten inside the tungsten film 252 decreases and the specific resistance of a word line increases.

In the present embodiment, the particle size of tungsten crystal particles included in the tungsten film 52 can be reduced in a formation process of the tungsten film 52. Thus, it is thought that the surface roughness of the tungsten crystal layer growing in the upward direction along the Z-axis direction and the surface roughness of the tungsten crystal layer growing in the downward direction along the Z-axis direction in the formation process of the tungsten film 52 become relatively small, and accordingly, it is thought that a gap is unlikely to be generated, for example, in a region near the center of the formed tungsten film 52 in the Z-axis direction and blockage of an opening part of the gap is unlikely to occur. As a result, it is thought that the filling rate of tungsten crystal in the tungsten film 52 according to the present embodiment improves as compared to the semiconductor device 200 of the comparative example, and increase in the specific resistance of a word line is reduced despite reduction of the particle size of tungsten crystal particles included in the tungsten film 52.

When the particle size of tungsten crystal particles included in the tungsten film 252 is relatively large as in the semiconductor device 200 of the comparative example and a gap is generated in a region near the center of the tungsten film 252 in the film thickness direction (Z-axis direction), fluorine atom diffusion is potentially evoked due to tungsten hexafluoride (WF₆) used in deposition and existing near the gap. It is thought that the fluorine atom diffusion occurs from the surface of the tungsten film, in particular, and it is thought that, since the gap is generated between the surface of the tungsten crystal layer growing in the upward direction along the Z-axis direction and the surface of the tungsten crystal layer growing in the downward direction along the Z-axis direction as described above, the surface of the tungsten crystal layer growing in the upward direction along the Z-axis direction and the surface of the tungsten crystal layer growing in the downward direction along the Z-axis direction are likely to be exposed, and accordingly, the fluorine atom diffusion from the tungsten film surface is likely to occur. It is thought that fluorine atoms diffuse into the insulator layer 251 formed of, for example, a material containing silicon oxide and potentially damage the insulator layer 251. In the present embodiment, since a gap is unlikely to be generated in a region near the center of the tungsten film 52 in the film thickness direction (Z-axis direction) as described above, fluorine atom diffusion can be reduced.

A manufacturing step of a semiconductor device including an increased number of stacked layers, in particular, could not be efficiently advanced in some cases due to the above-described occurrence of downward warping of a silicon wafer of a semiconductor substrate and/or the above-described occurrence of damage on an insulating film (insulator layer) due to fluorine atom diffusion. According to the method of manufacturing the semiconductor device 10 according to the present embodiment, the efficiency of manufacturing of the semiconductor device 10 can be improved since the occurrence of downward warping of a silicon wafer of a semiconductor substrate is reduced and/or the occurrence of damage on an insulating film due to fluorine atom diffusion is reduced. Thus, the method of manufacturing the semiconductor device 10 according to the present embodiment is particularly effective in a complicated manufacturing step of a recent semiconductor device including an increased number of stacked layers (for example, 100 layers or more).

As described above, the new creation film 57 in the semiconductor device 10 according to the present embodiment is formed using, for example, treatment gas containing tungsten hexafluoride (WF₆) gas and diborane (B₂H₆) gas as primary components. Thus, a layer containing boron (B) attributable to diborane (B₂H₆) gas may exist in the barrier metal film 56 and the tungsten film 52 formed on the front and back surface sides, respectively, of the new creation film 57 in the semiconductor device 10. It is thought that boron (B) attributable to diborane (B₂H₆) gas diffuses into the tungsten film 52 formed on the new creation film 57, and the boron concentration in the tungsten film 52 is higher in a region closer to the barrier metal film 56 and lower in a region farther from the barrier metal film 56. Thus, the tungsten film 52 may contain B at a first concentration at a position P closer to the barrier metal film 56 and contain B at a second concentration lower than the first concentration at a position Q farther from the barrier metal film 56 than the position P. In other words, in the tungsten film 52, a higher-boron-concentration region may be formed in a region closer to the barrier metal film 56.

The distribution of boron concentration in the tungsten film 52 may be measured by using, for example, a secondary ion mass spectrometry (SIMS). The distribution of boron concentration may be measured, for example, from a side of the tungsten film 52 in the film thickness direction (Z-axis direction), a side being closer to the barrier metal film 56, in the direction departing from the barrier metal film 56.

In the semiconductor device 10 according to the present embodiment, the conductive layer 52 is formed by providing the tungsten film 52. However, the tungsten film 52 may contain any other material such as boron (B) than tungsten, which is contained in a material used in, for example, a manufacturing step as described above. The above-described embodiments include the following numbered clauses:

### Clause 1

The semiconductor device including:
a plurality of insulating films; and
a plurality of tungsten films provided on the plurality of insulating films, respectively, and having a peak at orientation (110) and a peak at orientation (211).

### Clause 2

The semiconductor device according to clause 1, including:
the plurality of insulating films;
the plurality of tungsten films;
a semiconductor channel extending in a direction in which the semiconductor channel extends through the plurality of insulating films and the plurality of tungsten films; and
a charge storage film provided between the plurality of tungsten films and the semiconductor channel.

### Clause 3

A semiconductor device including:
an insulating film; and
a tungsten film provided on the insulating film, the tungsten film having a crystal particle, wherein a thickness T of the tungsten film and an average particle size APS of the crystal particle satisfy APS/T≤2.

### Clause 4

The semiconductor device according to clause 3, including:
a plurality of the insulating films;
a plurality of the tungsten films provided on the plurality of insulating films, respectively;
a semiconductor channel extending in a direction in which the semiconductor channel extends through the plurality of insulating films and the plurality of tungsten films; and
a charge storage film provided between the plurality of tungsten films and the semiconductor channel.

The present embodiment is described above with reference to specific examples. However, the present disclosure is not limited to these specific examples. Those obtained by changing designing of the specific examples as appropriate by the skilled person in the art are included in the scope of the present disclosure as long as they have features of the present disclosure. Each element included in each above-described specific example and, for example, the disposition, condition, and shape thereof are not limited to those exemplarily shown but may be changed as appropriate. Combination of elements included in the above-described specific examples may be changed as appropriate without technological inconsistency.

What is claimed is:

1. A semiconductor device comprising:
a first insulating film;
a second insulating film; and
a tungsten film provided between the first insulating film and the second insulating film, the tungsten film having a crystal particle, wherein a thickness T of the tungsten film in a first direction from the first insulating film toward the second insulating film and an average particle size APS of the crystal particle satisfy APS/T≤2.

2. The semiconductor device according to claim 1, wherein the thickness T of the tungsten film is 60 nm or less.

3. The semiconductor device according to claim 1, wherein the average particle size APS of the crystal particle of the tungsten film is 50 nm or less.

4. The semiconductor device according to claim 1, wherein the tungsten film has a peak at orientation (110) and a peak at orientation (211).

5. The semiconductor device according to claim 1, further comprising a barrier metal film covering the tungsten film.

6. The semiconductor device according to claim 5, wherein the barrier metal film contains TiN.

7. The semiconductor device according to claim 1, wherein the tungsten film contains B.

8. The semiconductor device according to claim 7, further comprising a barrier metal film covering the tungsten film, wherein the tungsten film contains B at a first concentration at a position P closer to the barrier metal film and contains B at a second concentration lower than the first concentration at a position Q farther from the barrier metal film than the position P.

9. The semiconductor device according to claim 1, wherein a ratio APS/T of the average particle size APS relative to the thickness T of the tungsten film is 1 or less.

10. The semiconductor device according to claim 1, wherein a ratio APS/T of the average particle size APS relative to the thickness T of the tungsten film is 0.3 or more.

11. The semiconductor device according to claim 1, further comprising:
a semiconductor channel extending through the first insulating film, the second insulating film, and the tungsten film in the first direction; and
a charge storage film provided between the tungsten film and the semiconductor channel.

12. The semiconductor device according to claim 1, further comprising:
a substrate,
wherein the first direction is a vertical direction against the substrate.
